(19) United States
(12) Patent Application Publication
(10) Pub. No.: US 2025/0277111 A1
(43) Pub. Date: Sep. 4, 2025

(54) RESIN COMPOSITION, PREPREG, LAMINATED PLATE, PRINTED WIRING BOARD, AND SEMICONDUCTOR PACKAGE

(71) Applicant: Resonac Corporation, Minato-ku, Tokyo (JP)

(72) Inventors: Norihiko SAKAMOTO, Minato-ku, Tokyo (JP); Kyousuke SUTOU, Minato-ku, Tokyo (JP); Yoshiya SUNAIRI, Minato-ku, Tokyo (JP); Shinji SHIMAOKA, Minato-ku, Tokyo (JP)

(21) Appl. No.: 18/859,568

(22) PCT Filed: Mar. 22, 2024
(86) PCT No.: PCT/JP2024/011197

§ 371 Date: Oct. 24, 2024

(30) Foreign Application Priority Data
Apr. 5, 2023 (JP) 2023-061207

(51) Int. Cl. C08L 79/08; C08J 5/24; C08K 3/22; C08K 3/36; C08K 7/18; C08K 9/02

(52) U.S. Cl. CPC C08L 79/08; C08J 5/244; C08K 3/22; C08K 3/36; C08K 7/18; C08K 9/02; C08J 2379/08; C08J 2463/02; C08K 2201/005; C08L 2203/20

(57) ABSTRACT

The present invention relates to a resin composition containing (A) a thermosetting resin and (B) a molybdenum compound supported on a silica, as well as a prepreg, a laminate, a printed wiring board, and a semiconductor package, all of which use the said resin composition.

### TECHNICAL FIELD

The present embodiment relates to a resin composition, a prepreg, a laminate, a printed wiring board, and a semiconductor package.

### BACKGROUND ART

In recent years, in a printed wiring board used in an electronic device, a communication device, and the like, requirements are increasing to reduce size and wight, to increase the density of wiring and the computation speed, among other things. With this trend, a reliability higher than ever is being required on an insulating layer of a printed wiring board.

As for the insulating layer in a printed wiring board, a prepreg having a fiber substrate such as a glass cloth impregnated with a resin composition has been used. In the production process of a printed wiring board, a cured product of the prepreg may be drilled to form a hole. In such a case especially when a basis weight of the fiber substrate is large, there may be deterioration in a drilling processability, such as decrease in accuracy of the hole-drilling position due to hardness of the fiber substrate.

In recent years, in order to lower a thermal expansion coefficient of the insulating layer, there are cases, for example, to increase an amount of an inorganic filler or to use a further harder fiber substrate; but this results in more eminent deterioration in the drilling processability.

As for the method to enhance the drilling processability, the technology has been known to add zinc molybdate to a resin composition. In Patent Document 1, the resin composition containing a molybdate compound supported on an inorganic particle is disclosed.

### CITATION LIST

### Patent Document

Patent Document 1: Japanese Patent Laid-Open Publication No. 2019-199562

### SUMMARY OF THE INVENTION

### Problems to be Solved by the Invention

However, on the basis of the study by the inventors of the present invention, it has been clarified that the prepreg formed by the resin composition containing the molybdate compound that is supported on the inorganic particle is poor in an adhesion to copper foil (hereinafter, this is also referred to as “copper foil adhesivity”).

In view of the present circumstances as described above, an object of the present embodiment is to provide: a resin composition that is superior in the drilling processability and copper foil adhesivity; and a prepreg, a laminate, a printed wiring board, and a semiconductor package, all of which use the said resin composition.

### Means for Solving the Problems

The inventors of the present invention studied extensively to solve the problems described above, and as a result, they found that it was possible to solve these problems by the present embodiment described below. On the basis of this finding, the present embodiment was completed.

That is, the present embodiment relates to following [1] to [13].

[1]A resin composition containing (A) a thermosetting resin and (B) a molybdenum compound supported on a silica.
[2] The resin composition according to [1], in which the component (B) is spherical.
[3] The resin composition according to [1] or [2], in which an average particle diameter (D₅₀) of the component (B) is 0.1 to 20 μm.
[4] The resin composition according to any one of [1] to [3], in which a supporting rate of the molybdenum compound in the composition (B) is 5 to 40% by mass.
[5] The resin composition according to any one of [1] to [4], in which the molybdenum compound is a metal molybdate salt.
[6] The resin composition according to any one of [1] to [5], in which a content of the component (B) relative to total amount of a solid portion (100% by mass) in the resin composition is 0.1 to 20% by mass.
[7] The resin composition according to any one of [1] to [6], in which the thermosetting resin includes at least one selected from the group consisting of a maleimide resin having at least one N-substituted maleimide group and a derivative of the said maleimide resin.
[8] The resin composition according to [7], in which the thermosetting resin further includes an epoxy resin.
[9]A prepreg including the resin composition according to any one of [1] to [8] and a fiber substrate.
[10] The prepreg according to [9], in which the fiber substrate is a glass cloth.
[11]A laminate having a cured product of the resin composition according to any of [1] to [8] and metal foil.
[12]A printed wiring board having a cured product of the resin composition according to any of [1] to [8].
[13]A semiconductor package having the printed wiring board according to [12] and a semiconductor element.

### Advantageous Effects of Invention

According to the present embodiment, what is provided is a resin composition that is superior in a drilling processability and copper foil adhesivity, as well as a prepreg, a laminate, a printed wiring board, and a semiconductor package, all of which use the said resin composition.

### DESCRIPTION OF THE EMBODIMENT

In this specification, the numeral range expressed by the word “to” indicates that the numerical value described before and after the word “to” is included as the minimum and maximum values, respectively.

For example, the expression of the numeral range by “X to Y” (X and Y are real numbers) means the numerical range of X or more and Y or less. The description “X or more” in this specification means the numerical value of X and the numerical value of more than X. In the same way, the description “Y or less” in this specification means the numerical value of Y and the numerical value of less than Y.

The upper and lower limits of the numeral range described in this specification may be arbitrarily combined with the upper and lower limits of other numeral range, respectively.

In the numeral range described in this specification, the upper and lower limit values of the numeral range may be substituted by the values described in Examples.

Each component and material described as an example in this specification may be used singly or in a combination of two or more of them, unless otherwise specifically mentioned.

In this specification, the content of each component in the resin composition, in the case where a plurality of substances corresponding to each component is present in a resin composition, means a total amount of the components present in the resin composition, unless otherwise specifically mentioned.

In this specification, the term “solid portion” means the components other than an organic solvent; thus, a component that is in the state of liquid at 25° C. is regarded also as the solid portion.

The expression “contains XX” used in this specification means both that XX is contained as it is and that when XX is capable of reaction XX is contained in the state of being reacted.

The weight-average molecular weight (Mw) in this specification means the value in terms of polystyrene measured by a gel permeation chromatography (GPC). Specifically, the weight-average molecular weight (Mw) in this specification may be measured by the method described in Examples.

In this specification, the term “cured product” is the same meaning as the state of C-stage of a resin composition as defined in JIS K 6800 (2006).

The action mechanism described in this specification is mere presumption, thereby not limiting the mechanism that expresses the advantageous effects of the present embodiment.

Embodiments in any combination of the items described in this specification are included in the present embodiment.

### [Resin Composition]

The resin composition according to the present embodiment contains (A) a thermosetting resin and (B) a molybdenum compound supported on a silica.

Hereinafter, the components and so forth that make up the resin composition according to the present embodiment will be explained one by one.

### <(a) Thermosetting Resin>

Illustrative examples of the thermosetting resin include an epoxy resin, a phenol resin, a maleimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.

The thermosetting resin (A) may be used singly or in a combination of 2 or more of those described above.

As for the thermosetting resin (A), among these, from the viewpoints of a heat resistance and a copper foil adhesion, a maleimide resin, an epoxy resin, and a cyanate resin are preferable, and a maleimide resin and an epoxy resin are more preferable.

### (Maleimide Resin)

The maleimide resin is preferably at least one selected from the group consisting of a maleimide resin having at least one N-substituted maleimide group and a derivative of the said maleimide resin.

Note that in the description hereinafter, “at least one selected from the group consisting of a maleimide resin having at least one N-substituted maleimide group and a derivative of the said maleimide resin” are sometimes collectively referred to as “maleimide-based resin”.

In the description hereinafter, the maleimide resin having at least one N-substituted maleimide group is sometimes referred to as “maleimide resin (AX)” or “component (AX)”.

Also, in the description hereinafter, the derivative of the maleimide resin having at least one N-substituted maleimide group is sometimes referred to as “maleimide resin derivative (AY)” or “component (AY)”.

### -Maleimide Resin (AX)-

There is no particular restriction in the maleimide resin (AX) as long as this is the maleimide resin having at least one N-substituted maleimide group.

From the viewpoints of a copper foil adhesivity and a heat resistance, the maleimide resin (AX) is preferably an aromatic maleimide resin having two or more N-substituted maleimide groups, and more preferably an aromatic maleimide resin having two N-substituted maleimide groups.

In this specification, the term “aromatic maleimide resin” means the compound having an N-substituted maleimide group directly bonded to an aromatic ring.

In this specification, the term “aromatic bismaleimide resin” means the compound having two N-substituted maleimide groups directly bonded to an aromatic ring.

In this specification, the term “aromatic polymaleimide resin” means the compound having three or more N-substituted maleimide groups directly bonded to an aromatic ring.

In this specification, the term “aliphatic maleimide resin” means the compound having an N-substituted maleimide group directly bonded to an aliphatic hydrocarbon.

As for the maleimide resin (AX), the maleimide resin represented by the following general formula (A1-1) (hereinafter, this is referred to as “maleimide resin (A1)”) is preferable.

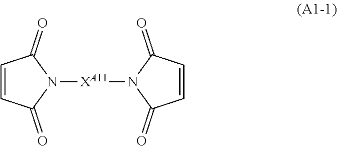

(In the formula, X^{A11} represents a divalent organic group.)

In the above general formula (A1-1), X^{A11} represents a divalent organic group.

Illustrative examples of the divalent organic group represented by X^{A11} in the above general formula (A1-1) include a divalent organic group represented by the following general formula (A1-2), a divalent organic group represented by the following general formula (A1-3), a divalent organic group represented by the following general formula (A1-4), a divalent organic group represented by the following general formula (A1-5), and a divalent organic group represented by the following general formula (A1-6).

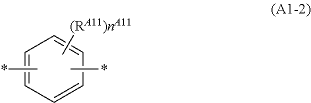

(In the formula, R^{A11} represents an aliphatic hydrocarbon group having the carbon number of 1 to 5 or a halogen atom, n^{A11} represents an integer of 0 to 4, and the symbol*represents a bonding site.)

Illustrative examples of the aliphatic hydrocarbon group having the carbon number of 1 to 5 represented by R^{A11} in the above general formula (A1-2) include: an alkyl group having the carbon number of 1 to 5, such as a methyl group, an ethyl group, an n-propyl group, an isopropyl group, an n-butyl group, an isobutyl group, a t-butyl group, and an n-pentyl group; an alkenyl group having the carbon number of 2 to 5, and an alkynyl group having the carbon number of 2 to 5. The aliphatic hydrocarbon group having the carbon number of 1 to 5 may be any of linear and branched.

Illustrative examples of the halogen atom include a fluorine atom, a chlorine atom, a bromine atom, and an iodine atom.

In the above general formula (A1-2), n^{A11} represents an integer of 0 to 4; from the viewpoint of an availability, this is preferably an integer of 0 to 2, more preferably 0 or 1, and still more preferably 0.

When n^{A11} is an integer of 2 or more, a plurality of R^{A11} may be same or different with each other.

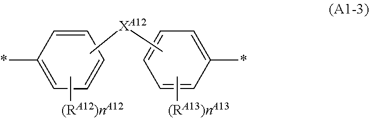

(In the formula, R^{A12} and R^{A13} each independently represent an aliphatic hydrocarbon group having the carbon number of 1 to 5 or a halogen atom. X^{A12} represents an alkylene group having the carbon number of 1 to 5, an alkylidene group having the carbon number of 2 to 5, an ether group, a sulfide group, a sulfonyl group, a carbonyloxy group, a keto group, a single bond, or a divalent organic group represented by the flowing general formula (A1-3-1). Here, n^{A12} and n^{A13} each independently represent an integer of 0 to 4, and the symbol*represents a bonding site.)

In the above general formula (A1-3), illustrative examples of the aliphatic hydrocarbon group having the carbon number of 1 to 5 represented by R^{A12} and R^{A13} include an alkyl group having the carbon number of 1 to 5, such as a methyl group, an ethyl group, an n-propyl group, an isopropyl group, an n-butyl group, an isobutyl group, a t-butyl group, and an n-pentyl group; an alkenyl group having the carbon number of 2 to 5, and an alkynyl group having the carbon number of 2 to 5. The aliphatic hydrocarbon group having the carbon number of 1 to 5 may be any of linear and branched. The aliphatic hydrocarbon group having the carbon number of 1 to 5 is preferably an aliphatic hydrocarbon group having the carbon number of 1 to 3, more preferably an alkyl group having the carbon number of 1 to 3, and still more preferably a methyl group and an ethyl group.

Illustrative examples of the halogen atom include a fluorine atom, a chlorine atom, a bromine atom, and an iodine atom.

Illustrative examples of the alkylene group having the carbon number of 1 to 5 represented by X^{A12} in the above general formula (A1-3) include a methylene group, a 1,2-dimethylene group, a 1,3-trimethylene group, a 1,4-tetamethylene group, and 1,5-pentamethylene group. The alkylene group having the carbon number of 1 to 5 is preferably an alkylene group having the carbon number of 1 to 3, more preferably an alkylene group having the carbon number of 1 or 2, and still more preferably a methylene group.

Illustrative examples of the alkylidene group having the carbon number of 2 to 5 represented by X^{A12} in the above general formula (A1-3) include an ethylidene group, a propylidene group, an isopropylidene group, a butylidene group, an isobutylidene group, a pentylidene group, and an isopentylidene group. Among these, an alkylidene group having the carbon number of 2 to 4 is preferable, an alkylidene group having the carbon number of 2 or 3 is more preferable, and an isopropylidene group is still more preferable.

In the above general formula (A1-3), n^{A12} and n^{A13} each independently represent an integer of 0 to 4.

When n^{A12} or n^{A13} is an integer of 2 or more, a plurality of R^{A12} or a plurality of R^{A13} may be same or different with each other.

The divalent organic group X^{A12} represented by the general formula (A1-3-1) in the above general formula (A1-3) is as follows.

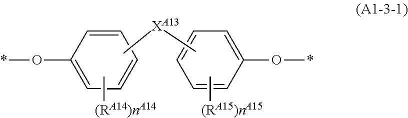

(In the formula, R^{A14} and R^{A15} each independently represent an aliphatic hydrocarbon group having the carbon number of 1 to 5 or a halogen atom. X^{A13} represents an alkylene group having the carbon number of 1 to 5, an alkylidene group having the carbon number of 2 to 5, an ether group, a sulfide group, a sulfonyl group, a carbonyloxy group, a keto group, or a single bond. Here, n^{A14} and n^{A15} each independently represent an integer of 0 to 4, and the symbol*represents a bonding site.)

Illustrative examples of the aliphatic hydrocarbon group having the carbon number of 1 to 5 represented by R^{A14} and R^{A15} in the above general formula (A1-3-1) include: an alkyl group having the carbon number of 1 to 5, such as a methyl group, an ethyl group, an n-propyl group, an isopropyl group, an n-butyl group, an isobutyl group, a t-butyl group, and an n-pentyl group; an alkenyl group having the carbon number of 2 to 5, and an alkynyl group having the carbon number of 2 to 5. The aliphatic hydrocarbon group having the carbon number of 1 to 5 may be any of linear and branched.

Illustrative examples of the halogen atom include a fluorine atom, a chlorine atom, a bromine atom, and an iodine atom.

Illustrative examples of the alkylene group having the carbon number of 1 to 5 represented by X^{A13} in the above general formula (A1-3-1) include a methylene group, a 1,2-dimethylene group, a 1,3-trimethylene group, a 1,4-tetamethylene group, and 1,5-pentamethylene group. The alkylene group having the carbon number of 1 to 5 is preferably an alkylene group having the carbon number of 1 to 3, more preferably an alkylene group having the carbon number of 1 or 2, and still more preferably a methylene group.

Illustrative examples of the alkylidene group having the carbon number of 2 to 5 represented by X^{A13} in the above general formula (A1-3-1) include an ethylidene group, a propylidene group, an isopropylidene group, a butylidene group, an isobutylidene group, a pentylidene group, and an isopentylidene group. Among these, an alkylidene group having the carbon number of 2 to 4 is preferable, an alkylidene group having the carbon number of 2 or 3 is more preferable, and an isopropylidene group is still more preferable.

Among the choices of X^{A13} in the above general formula (A1-3-1), an alkylidene group having the carbon number of 2 to 5 is preferable, an alkylidene group having the carbon number of 2 to 4 is more preferable, and an isopropylidene group is still more preferable.

In the above general formula (A1-3-1), n^{A14} and n^{A15} each independently represent an integer of 0 to 4. From the viewpoint of an availability, they are preferably an integer of 0 to 2, more preferably 0 or 1, and still more preferably 0.

When n^{A14} or n^{A15} is an integer of 2 or more, a plurality of R^{A14} or a plurality of R^{A15} may be same or different with each other.

Among the choices of X^{A12} in the above general formula (A1-3), an alkylene group having the carbon number of 1 to 5, an alkylidene group having the carbon number of 2 to 5, and a divalent group represented by the above general formula (A1-3-1) are preferable, an alkylene group having the carbon number of 1 to 5 is more preferable, and a methylene group is still more preferable.

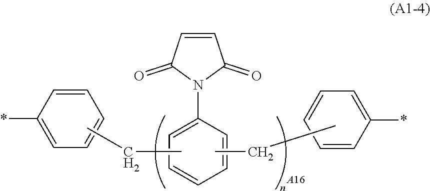

(In the formula, n^{A16} represents an integer of 0 to 10, and the symbol*represents a bonding site.)

From the viewpoint of an availability, n^{A16} in the above general formula (A1-4) is preferably an integer of 0 to 5, more preferably an integer of 0 to 4, and still more preferably an integer of 0 to 3.

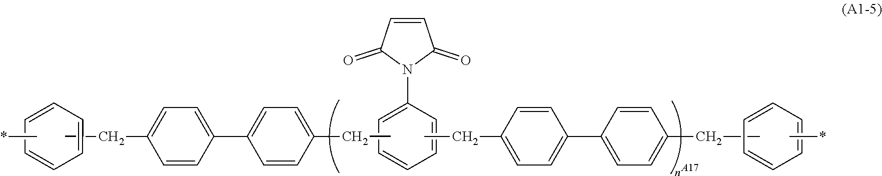

(In the formula, n^{A17} represents an integer of 0 to 5, and the symbol*represents a bonding site.)

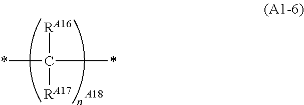

(In the formula, R^{A16} and R^{A17} each independently represent a hydrogen atom or an aliphatic hydrocarbon group having the carbon number of 1 to 5, n^{Al8} represents an integer of 1 to 8, and the symbol*represents a bonding site.)

Illustrative examples of the aliphatic hydrocarbon group having the carbon number of 1 to 5 represented by R^{A16} and R^{A17} in the above general formula (A1-6) include: an alkyl group having the carbon number of 1 to 5, such as a methyl group, an ethyl group, an n-propyl group, an isopropyl group, an n-butyl group, an isobutyl group, a t-butyl group, and an n-pentyl group; an alkenyl group having the carbon number of 2 to 5, and an alkynyl group having the carbon number of 2 to 5. The aliphatic hydrocarbon group having the carbon number of 1 to 5 may be any of linear and branched.

In the above general formula (A1-6), n^{Al8} is an integer of 1 to 8, preferably an integer of 1 to 5, more preferably an integer of 1 to 3, and still more preferably 1. When n^{Al8} is an integer of 2 or more, a plurality of R^{A16} and R^{A17} may be same or different with each other.

Illustrative examples of the maleimide resin (A1) include an aromatic bismaleimide resin, an aromatic polymaleimide resin, and an aliphatic maleimide resin.

Illustrative examples of the maleimide resin (A1) include bis(4-maleimidephenyl)methane, m-phenylene bismaleimide, 2,2-bis[4-(4-maleimidephenoxy)phenyl]propane, 4-methyl-1,3-phenylene bismaleimide, 3,3′-dimethyl-5,5′-diethyl-4,4′-diphenylmethane bismaleimide, polyphenylmethane maleimide, a biphenylaralkyl type maleimide, and an aromatic bismaleimide resin having an indane skeleton. Among these, 2,2-bis[4-(4-maleimidephenoxy)phenyl]propane is preferable.

### -Maleimide Resin Derivative (AY)-

As for the maleimide resin derivative (AY), a resin containing a structure originated from the above-mentioned maleimide resin (AX)) and a structure originated from a diamine compound is preferable (hereinafter, this is sometimes referred to as “aminomaleimide resin (A2)”, or simply “component (A2)”).

### -Aminomaleimide Resin (A2)-

The aminomaleimide resin (A2) has a structure originated from the maleimide resin (AX)) and a structure originated from a diamine compound.

<<Structure Originated from Maleimide Resin (AX)>>

As for the structure originated from the maleimide resin (AX), for example, the structure formed by the Michael addition reaction in which at least one N-substituted maleimide group among the N-substituted maleimide groups that are contained in the maleimide resin (AX) is reacted with an amino group contained in the diamine compound may be mentioned.

The structure originated from the maleimide resin (AX) contained in the aminomaleimide resin (A2) may be one structure alone, or two or more structures.

There is no particular restriction in the content of the structure originated from the maleimide resin (AX) in the aminomaleimide resin (A2); the content is preferably in the range of 5 to 95% by mass, more preferably in the range of 30 to 93% by mass, and still more preferably in the range of 60 to 90% by mass.

When the content of the structure originated from the maleimide resin (AX) in the aminomaleimide resin (A2) is within the above-mentioned range, dielectric characteristics and a handling property when it is made to a resin film are prone to be further enhanced.

<<Structure Originated from Diamine Compound>>

As for the structure originated from the diamine compound, for example, the structure formed by the Michael addition reaction in which one or both amino groups of the two amino groups that are contained in the diamine compound is reacted with an N-substituted maleimide group contained in the maleimide resin (AX) may be mentioned.

The structure originated from the diamine compound contained in the aminomaleimide resin (A2) may be one structure, or two or more structures.

The amino group contained in the diamine compound is preferably a primary amino group.

Illustrative examples of the structure originated from the diamine compound having two primary amino groups include the group represented by the following general formula (A2-1) and the group represented by the following general formula (A2-2).

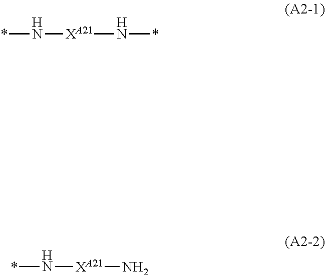

(In these formulae, X^{A21} is a divalent organic group, and the symbol*represents a bonding site.)

In the general formula (A2-1) and general formula (A2-2), X^{A2}1 represents a divalent organic group that corresponds to a divalent group having two primary amino groups removed from the diamine compound.

In the general formula (A2-1) and general formula (A2-2), X^{A21} is preferably a divalent group represented by the following general formula (A2-3).

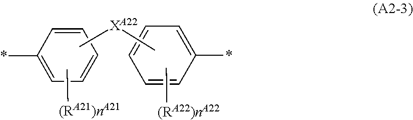

(In the formula, R^{A21} and R^{A22} each independently represent an aliphatic hydrocarbon group having the carbon number of 1 to 5, an alkoxy group having the carbon number of 1 to 5, a hydroxy group, or a halogen atom. X^{A22} represents an alkylene group having the carbon number of 1 to 5, an alkylidene group having the carbon number of 2 to 5, an ether group, a sulfide group, a sulfonyl group, a carbonyloxy group, a keto group, a fluorenyl group, a single bond, or a divalent group represented by the flowing general formula (A2-3-1) or the flowing general formula (A2-3-2). Here, n^{A21} and n^{A22} each independently represent an integer of 0 to 4, and the symbol*represents a bonding site.)

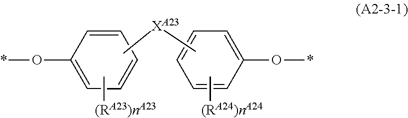

(In the formula, R^{A23} and R^{A24} each independently represent an aliphatic hydrocarbon group having the carbon number of 1 to 5 or a halogen atom. X^{A23} represents an alkylene group having the carbon number of 1 to 5, an alkylidene group having the carbon number of 2 to 5, a m-phenylenediisopropylidene group, a p-phenylenediisopropylidene group, an ether group, a sulfide group, a sulfonyl group, a carbonyloxy group, a keto group, or a single bond. Here, n^{A23} and n^{A24} each independently represent an integer of 0 to 4, and the symbol*represents a bonding site.)

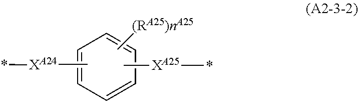

(In the formula, R^{A25} represents an aliphatic hydrocarbon group having the carbon number of 1 to 5 or a halogen atom. X^{A24} and X^{A25} each independently represent an alkylene group having the carbon number of 1 to 5, an alkylidene group having the carbon number of 2 to 5, an ether group, a sulfide group, a sulfonyl group, a carbonyloxy group, a keto group, or a single bond. Here, n^{A25} represents an integer of 0 to 4, and the symbol*represents a bonding site.)

Illustrative examples of the aliphatic hydrocarbon group having the carbon number of 1 to 5 represented by R^{A21}, R^{A22}, R^{A23}, R^{A24}, and R^{A25} in the general formula (A2-3), in the general formula (A2-3-1), and in the general formula (A2-3-2) include: an alkyl group having the carbon number of 1 to 5, such as a methyl group, an ethyl group, an n-propyl group, an isopropyl group, an n-butyl group, an isobutyl group, a t-butyl group, and an n-pentyl group; an alkenyl group having the carbon number of 2 to 5, and an alkynyl group having the carbon number of 2 to 5. The aliphatic hydrocarbon group having the carbon number of 1 to 5 may be any of linear and branched. The aliphatic hydrocarbon group having the carbon number of 1 to 5 is preferably an aliphatic hydrocarbon group having the carbon number of 1 to 3, more preferably an alkyl group having the carbon number of 1 to 3, and still more preferably a methyl group and an ethyl group. Illustrative examples of the halogen atom include a fluorine atom, a chlorine atom, a bromine atom, and an iodine atom.

Illustrative examples of the alkylene group having the carbon number of 1 to 5, represented by X^{A22} in the general formula (A2-3), X^{A23} in the general formula (A2-3-1), and X^{A24} and X^{A25} in the general formula (A2-3-2) include a methylene group, a 1,2-dimethylene group, a 1,3-trimethylene group, a 1,4-tetamethylene group, and 1,5-pentamethylene group. The alkylene group having the carbon number of 1 to 5 is preferably an alkylene group having the carbon number of 1 to 3, more preferably an alkylene group having the carbon number of 1 or 2, and still more preferably a methylene group.

Illustrative examples of the alkylidene group having the carbon number of 2 to 5, represented by X^{A22} in the general formula (A2-3), X^{A23} in the general formula (A2-3-1), and X^{A24} and X^{A25} in the general formula (A2-3-2) include an ethylidene group, a propylidene group, an isopropylidene group, a butylidene group, an isobutylidene group, a pentylidene group, and an isopentylidene group. The alkylidene group having the carbon number of 2 to 5 is preferably an alkylidene group having the carbon number of 2 to 4, more preferably an alkylidene group having the carbon number of 2 or 3, and still more preferably an isopropylidene group.

In the above general formula (A2-3), n^{A2}1 and n^{A22} each independently represent an integer of 0 to 4; from the viewpoint of an availability, they are preferably an integer of 0 to 3, more preferably an integer of 0 to 2, and still more preferably 0 or 2.

When n^{A21} or n^{A22} is an integer of 2 or more, a plurality of R^{A21} or a plurality of R^{A22} may be same or different with each other.

In the above general formula (A2-3-1), n^{A23} and n^{A24} each independently represent an integer of 0 to 4; from the viewpoint of an availability, they are preferably an integer of 0 to 2, more preferably an integer of 0 or 1, and still more preferably 0.

When n^{A23} or n^{A24} is an integer of 2 or more, a plurality of R^{A23} or a plurality of R^{A24} may be same or different with each other.

In the above general formula (A2-3-2), n^{A25} represents an integer of 0 to 4; from the viewpoint of an availability, it is preferably an integer of 0 to 2, more preferably an integer of 0 or 1, and still more preferably 0.

When n^{A25} is an integer of 2 or more, a plurality of R^{A25} may be same or different with each other.

In the general formula (A2-1) and the general formula (A2-2), X^{A21} may be a divalent group having the structure represented by the following general formula (A2-4), or a divalent group represented by the following general formula (A2-5).

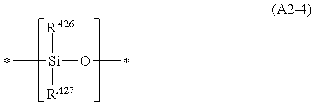

(In the formula, R^{A26} and R^{A27} each independently represent an aliphatic hydrocarbon group having the carbon number of 1 to 5, a phenyl group, or a substituted phenyl group; the symbol*represents a bonding site.)

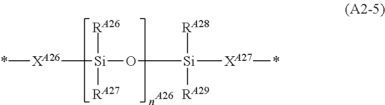

(In the formula, R^{A26} and R^{A27} represent the same as those in the general formula (A2-4); R^{A28} and R^{A29} each independently represent an aliphatic hydrocarbon group having the carbon number of 1 to 5, a phenyl group, or a substituted phenyl group; X^{A26} and X^{A27} each independently represent a divalent organic group; n^{A26} represents an integer of 2 to 100; and the symbol*represents a bonding site.)

Illustrative examples of the aliphatic hydrocarbon group having the carbon number of 1 to 5 represented by R^{A26} to R^{A29} in the general formulae (A2-4) and (A2-5) include: an alkyl group having the carbon number of 1 to 5, such as a methyl group, an ethyl group, an n-propyl group, an isopropyl group, an n-butyl group, an isobutyl group, a t-butyl group, and an n-pentyl group; an alkenyl group having the carbon number of 2 to 5, and an alkynyl group having the carbon number of 2 to 5. The aliphatic hydrocarbon group having the carbon number of 1 to 5 may be any of linear and branched. The aliphatic hydrocarbon group having the carbon number of 1 to 5 is preferably an aliphatic hydrocarbon group having the carbon number of 1 to 3, more preferably an alkyl group having the carbon number of 1 to 3, and still more preferably a methyl group.

The substituent of the phenyl group in the substituted phenyl group represented by R^{A26}to R^{A29} may be the aliphatic hydrocarbon group having the carbon number of 1 to 5 as described above.

Illustrative examples of the divalent organic group represented by X^{A26} and X^{A27} include an alkylene group, an alkenylene group, an alkynylene group, an arylene group, —O—, as well as a divalent connecting group in a combination of these groups.

Illustrative examples of the alkylene group include an alkylene group having the carbon number of 1 to 10, such as a methylene group, an ethylene group, and a propylene group. Illustrative examples of the alkenylene group include an alkenylene group having the carbon number of 2 to 10.

Illustrative examples of the alkynylene group include an alkynylene group having the carbon number of 2 to 10.

Illustrative examples of the arylene group include an arylene group having the carbon number of 6 to 20, such as a phenylene group and a naphthylene group.

Among these, as for X^{A26} and X^{A27}, an alkylene group and an arylene group are preferable, and an alkylene group is more preferable.

Here, n^{A26} is an integer of 2 to 100, preferably an integer of 2 to 50, more preferably an integer of 3 to 40, and still more preferably an integer of 5 to 30. When n^{A26} is an integer of 2 or more, a plurality of R^{A26} or a plurality of R^{A27} may be same or different with each other.

There is no particular restriction in the content of the structure originated from the diamine compound in the aminomaleimide resin (A2); this is preferably in the range of 5 to 95% by mass, more preferably in the range of 7 to 70% by mass, and still more preferably in the range of 10 to 40% by mass.

When the content of the structure originated from the diamine compound in the aminomaleimide resin (A2) is within the above-mentioned range, dielectric characteristics, a heat resistance, a flame retardance, and a glass transition temperature may be further improved.

Illustrative examples of the diamine compound include: an aromatic diamine compound such as 4,4′-diaminodiphenylmethane, 3,3′-dimethyl-4,4′-diaminodiphenylmethane, 3,3′-diethyl-4,4′-dimainodiphenylmethane, 2,2-bis[4-(4-aminophenoxy)phenyl]propane, 4,4′-[1,3-phenylenebis(1-methylethylidene)]bisaniline, 4,4′-[1,4-phenylenebis(1-methylethylidene)]bisaniline, and 3,3′-diethyl-4,4′-diaminodiphenylmethane; and a silicone compound having 2 primary amino groups. Among these, from the viewpoint of a low thermal expansion, 3,3′-diethyl-4,4′-diaminodiphenylmethane and a silicone compound having 2 primary amino groups are preferable.

Note that, in this specification, “aromatic diamine compound” refers to the compound having 2 amino groups bonded directly to an aromatic ring.

As for the silicone compound having two primary amines, the silicone compound having the primary amino groups at both molecular terminals thereof.

There is no particular restriction in the primary amine equivalent of the silicone compound having two primary amines; the equivalent is preferably in the range of 300 to 2,000 g/mol, more preferably in the range of 400 to 1,500 g/mol, and still more preferably in the range of 500 to 1,000 g/mol.

In the aminomaleimide resin (A2), there is no particular restriction in the equivalent ratio (Ta2/Ta1), where Ta2 is a total equivalent of the groups originated from the —NH₂ group in the diamine compound, and Ta1 is a total equivalent of the groups originated from the N-substituted maleimide group in the maleimide resin (AX); from the viewpoints of dielectric characteristics, a heat resistance, a flame retardance, and a glass transition temperature, the ratio is preferably in the range of 0.05 to 10, more preferably in the range of 1 to 8, and still more preferably in the range of 3 to 7. Note that the group originated from the —NH₂ group in the diamine compound includes the —NH₂ group itself, and that the group originated from the N-substituted maleimide group in the maleimide resin (AX) includes the N-substituted maleimide group itself.

There is no particular restriction in the weight-average molecular weight (Mw) of the aminomaleimide resin (A2). From the viewpoints of a handling property and a moldability, the molecular weight is preferably in the range of 400 to 10,000, more preferably in the range of 1,000 to 5,000, still more preferably in the range of 1,500 to 4,000, and especially preferably in the range of 2,000 to 3,000.

The aminomaleimide resin (A2) may be produced, for example, by causing the maleimide resin (AX) to react with the diamine compound in an organic solvent.

By causing the maleimide resin (AX) to react with the diamine compound, the aminomaleimide resin (A2) that is a product of the Michael addition reaction of the maleimide resin (AX) with the diamine compound may be produced.

At the time of causing the maleimide resin (AX) to react with the diamine compound, a reaction catalyst may be used as needed.

From the viewpoints of workability such as the reaction rate and of suppression of gelation of the product during the reaction, the reaction temperature of the Michael addition reaction is preferably in the range of 50 to 160° C., more preferably in the range of 60 to 150° C., and still more preferably in the range of 70 to 140° C.

From the viewpoints of productivity and of conducting the reaction sufficiently well, the reaction time of the Michael addition reaction is preferably in the range of 0.5 to 10 hours, more preferably in the range of 1 to 8 hours, and still more preferably in the range of 2 to 6 hours.

However, there is no particular restriction in these reaction conditions, so that the conditions may be adjusted as appropriate in accordance with the raw materials to be used.

### (Epoxy Resin)

It is preferable that the epoxy resin has two or more epoxy groups in its molecule.

The epoxy resin may be classified into a glycidyl ether type epoxy resin, a glycidylamine type epoxy resin, a glycidyl ester type epoxy resin, and the like. Among these, a glycidyl ether type epoxy resin is preferable.

The epoxy resin may also be classified into many epoxy resins in accordance with the difference in the main skeleton in the molecular structure thereof.

Specifically, the epoxy resin may be classified into, for example, a bisphenol type epoxy resin such as a bisphenol A type epoxy resin, a bisphenol F type epoxy resin, and a bisphenol S type epoxy resin; a novolac type epoxy resin such as a bisphenol A novolac type epoxy resin, a bisphenol F novolac type epoxy resin, a phenol novolac type epoxy resin, a cresol novolac type epoxy resin, a biphenyl novolac type epoxy resin, and a naphthol novolac type epoxy resin; an aralkyl type epoxy resin such as a phenolaralkyl type epoxy resin, a biphenylaralkyl type epoxy resin, and a naphtholaralkyl type epoxy resin; a stilbene type epoxy resin; a naphthylene ether type epoxy resin; a biphenyl type epoxy resin; a dihydroanthracene type epoxy resin; an epoxy resin containing a saturated dicyclopentadiene skeleton; a cyclohexanedimethanol type epoxy resin; an epoxy resin having a spiro ring; a heterocyclic epoxy resin; an alicyclic epoxy resin; an aliphatic chain epoxy resin; and a rubber-modified epoxy resin, among other epoxy resins. Among these epoxy resins, an epoxy resin having a biphenyl structure is preferable, and a biphenylaralkyl type epoxy resin is more preferable.

It is preferable that the resin composition according to the present embodiment includes, as the thermosetting resin (A), at least one selected from the group consisting of the maleimide resin having at least one N-substituted maleimide group and the derivative of the said maleimide resin. It is more preferable that the composition further includes the epoxy resin.

In the thermosetting resin (A), there is no particular restriction in the content of at least one selected from the group consisting of the maleimide resin having at least one N-substituted maleimide group and the derivative of the said maleimide resin; the content is preferably in the range of 50 to 95% by mass, more preferably in the range of 60 to 90% by mass, and still more preferably in the range of 70 to 85% by mass.

There is no particular restriction in the content of the epoxy resin in the thermosetting resin (A); the content is preferably in the range of 5 to 50% by mass, more preferably in the range of 10 to 40% by mass, and still more preferably in the range of 15 to 30% by mass.

There is no particular restriction in the content of the thermosetting resin (A) in the resin composition according to the present embodiment; the content relative to the total amount (100% by mass) of the resin components in the resin composition according to the present embodiment is preferably in the range of 30 to 100% by mass, more preferably in the range of 50 to 100% by mass, and still more preferably in the range of 80 to 100% by mass.

When the content of the thermosetting resin (A) is within the above-mentioned range, a heat resistance, a moldability, a processability, and a copper foil adhesivity are prone to be enhanced.

In this specification, the term “resin component” means a resin and a compound that forms a resin by a curing reaction. However, a curing accelerator (D) is not included in the resin component.

There is no particular restriction in the content of the resin component in the resin composition according to the present embodiment; the content relative to the total solid portion (100% by mass) in the resin composition according to the present embodiment is preferably in the range of 10 to 90% by mass, more preferably in the range of 20 to 70% by mass, and still more preferably in the range of 30 to 50% by mass.

When the content of the resin component is equal to or more than the above-mentioned lower limit value, a heat resistance, a moldability, a processability, and a copper foil adhesivity are prone to be enhanced. When the content of the resin component is equal to or less than the above-mentioned upper limit value, a low-thermal expansion may be further improved.

### <(B) Molybdenum Compound Supported on Silica>

There is no particular restriction in the component (B) as far as it is the molybdenum compound that is supported on silica.

Although there is no reason clarified yet, the resin composition according to the present embodiment is possible to express superior drilling processability and copper foil adhesivity when containing a molybdenum compound that is supported on silica.

Illustrative examples of the molybdenum compound include a metal molybdate salt, a molybdenum oxide, and an ammonium molybdate. Among these, from the viewpoints of a drilling processability and an adhesion to metal foil, a molybdate metal salt is preferable.

Illustrative examples of the metal molybdate salt include zinc molybdate, magnesium molybdate, calcium molybdate, strontium molybdate, barium molybdate, lithium molybdate, sodium molybdate, potassium molybdate, copper molybdate, iron molybdate, and zirconium molybdate. Among these, from the viewpoints of a drilling processability and a copper foil adhesivity, zinc molybdate is preferable.

The zinc molybdate in the present embodiment is a salt of zinc with molybdic acid with the composition of, for example, ZnₓMo_{y}O₄ (0.5<X<2.5, 0.5<Y<2.5) and ZnₓMo_{y}O₄(OH)_{z} (0.5<X<2.5, 0.5<Y<2.5, 0.5<Z<2.5).

There is no particular restriction in the average particle diameter (D₅₀) of the component (B). From the viewpoint of a copper foil adhesivity, this is preferably in the range of 0.1 to 20 m, more preferably in the range of 0.3 to 10 m, and still more preferably in the range of 0.4 to 1 μm.

In this specification, the average particle diameter (D₅₀) is the particle diameter at the point corresponding to the 50% volume in the cumulative frequency distribution curve of the particle diameter based on the 100% as the total volume of the particle. The average particle diameter (D₅₀) may be measured by using, for example, a particle size distribution measurement instrument with a laser diffraction scattering method.

The silica for supporting the molybdenum compound may be, for example, a precipitated silica with a high water content produced by a wet process or a silica hardly containing water such as bound water produced by a dry process. The silica produced by a dray process may be classified into, for example, a crushed silica, a fumed silica, and a fused silica in accordance with the production method. Among these, from the viewpoints of a dispersibility and a moldability, a fused silica is preferable.

There is no particular restriction in the form of the component (B); for example, a spherical form or a crushed form may be used. Among these, from the viewpoints of a copper foil adhesivity and suppressing the melt viscosity of the resin composition, a spherical form is preferable.

The term “spherical” in the present embodiment referrers to the circularity of 90 or more, calculated by the following formula using the area and circumferential length that is measured in the photo of the object particle.

Circularity={4π×(area)÷(circumferential length)²}×100

When the circularity is getting closer to 100, the particle is getting closer to a true spere. From the viewpoint of a copper foil adhesivity, the circularity of the component (B) of the present embodiment is preferably in the range of 90 to 100, more preferably in the range of 93 to 100, and still more preferably in the range of 95 to 100.

The more specific measurement method of the circularity will be described in Examples.

There is no particular restriction in the supporting rate of the molybdenum compound in the component (B). From the viewpoints of drilling characteristics and a copper foil adhesivity, the supporting rate is preferably in the range of 5 to 40% by mass, more preferably in the range of 7 to 35% by mass, and still more preferably in the range of 10 to 30% by mass. Note that the supporting rate of the molybdenum compound in the component (B) means the ratio of the mass of the molybdenum compound to the total mass of the component (B).

In the resin composition of the present embodiment, there is no particular restriction in the content of the component (B); the component relative to the total solid amount (100% by mass) in the resin composition is preferably in the range of 0.1 to 20% by mass, more preferably in the range of 0.5 to 17% by mass, still more preferably in the range of 1 to 15% by mass, further still more preferably in the range of 3 to 13% by mass, and especially preferably in the range of 7 to 12% by mass.

When the content of the component (B) is within the above-mentioned range, a drilling processability and a copper foil adhesivity are prone to be further enhanced.

### <(C) Inorganic Filler>

It is preferable that the resin composition of the present embodiment includes further an inorganic filler (C).

When the resin composition of the present embodiment includes the inorganic filler (C), further superior low-thermal expansion and heat resistance are prone to be obtained.

Note that in the present embodiment the component (B) is not included in the concept of the inorganic filler (C).

The inorganic filler (C) may be used singly or in a combination of two or more of it.

Illustrative examples of the inorganic filler (C) include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, talc, aluminum borate, and silicon carbide. Among these, from the viewpoints of a low thermal expansion, a heat resistance, and a flame retardance, silica, alumina, mica, and talc are preferable, silica and alumina are more preferable, and silica is still more preferable. The silica may be the same silica that supports the molybdenum compound in the component (B), as described before.

There is no particular restriction in the average particle diameter (D₅₀) of the inorganic filler (C). From the viewpoints of a dispersibility of the inorganic filler (C) and of a fine wiring, the average particle diameter is preferably in the range of 0.01 to 20 μm, more preferably in the range of 0.1 to 10 μm, still more preferably in the range of 0.2 to 5 μm, and especially preferably in the range of 0.3 to 2 μm.

The inorganic filler (C) may be, for example, a spherical form or a crushed form; a spherical form is preferable.

In order to enhance a dispersibility of the inorganic filler (C) and an adhesion between the inorganic filler (C) and the organic components, the resin composition of the present embodiment may use a coupling agent. The coupling agent may be, for example, a silane coupling agent and a titanate coupling agent. Among them, a silane coupling agent is preferable.

When the resin composition of the present embodiment includes the inorganic filler (C), there is no particular restriction in the content of the inorganic filler (C); the content thereof relative to the total solid portions (100% by mass) in the resin composition is preferably in the range of 10 to 80% by mass, more preferably in the range of 30 to 75% by mass, and still more preferably in the range of 40 to 70% by mass.

When the content of the inorganic filler (C) is equal to or more than the above-mentioned lower limit value, a low thermal expansion and a heat resistance are prone to be further enhanced. When the content of the inorganic filler (C) is equal to or less than the above-mentioned upper limit value, a moldability and a copper foil adhesivity are prone to be further enhanced.

### <(D) Curing Accelerator>

It is preferable that the resin composition of the present embodiment further contains a curing accelerator (D).

The resin composition of the present embodiment containing the curing accelerator (D) enhances a curing property thereof, so that a copper foil adhesivity is prone to be further enhanced.

The curing accelerator (D) may be used singly or in a combination of 2 or more of it.

Illustrative examples of the curing accelerator (D) include: an acid catalyst such as p-toluenesulfonic acid; an amine compound such as triethylamine, tributylamine, pyridine, and dicyandiamide; an imidazole compound such as methylimidazole, phenylimidazole, 1-cyanoethyl-2-phenylimidazole, and 1-cyanoethyl-2-phenylimidazolium trimellitate; an isocyanate-masked imidazole compound such as an addition reaction product of a hexamethylene diisocyanate resin with 2-ethyl-4-methyl imidazole; a quaternary ammonium compound; a phosphorous compound such as triphenylphosphine; an organic peroxide such as dicumyl peroxide, 2,5-dimethyl-2,5-bis(t-butylperoxy)hexyne-3, 2,5-dimethyl-2,5-bis(t-butylperoxy)hexane, t-butylperoxyisopropyl monocarbonate, and α,α′-bis(t-butylperoxy)diisopropylbenzene; an azo compound; and a carboxylate salt of manganese, cobalt, zinc, or the like;

Among these, from the viewpoints of a curing acceleration effect and a storage stability, an isocyanate-masked imidazole compound is preferable.

When the resin composition of the present embodiment contains the curing accelerator (D), there is no particular restriction in the content of the curing accelerator (D); the content relative to 100 parts by mass of the thermosetting resin (A) is preferably in the range of 0.01 to 10 parts by mass, more preferably in the range of 0.05 to 5 parts by mass, and still more preferably in the range of 0.1 to 1 part by mass.

When the content of the curing accelerator (D) is equal to or more than the above-mentioned lower limit value, a sufficient curing acceleration effect is prone to be obtained. When the content of the curing accelerator (D) is equal to or less than the above-mentioned upper limit value, a storage stability is prone to be further enhanced.

### <Other Optional Components>

The resin composition of the present embodiment may further contain, as needed, at least one other optional component selected from the group consisting of a resin material other than the components described above, a flame retardant, an antioxidant, a heat stabilizer, an antistatic agent, a UV absorber, a pigment, a colorant, a lubricant, an organic solvent, and an additive other than those described above.

Each of them may be used singly or in a combination of 2 or more of them.

There is no particular restriction in the use amount of these optional components; thus, they may be used as needed within the range not impair the advantageous effects of the present embodiment.

The resin composition of the present embodiment may not contain the above-mentioned optional components depending on the intended performance.

### (Organic Solvent)

From the viewpoint of an ease in handling, the resin composition of the present embodiment may contain an organic solvent.

The organic solvent may be used singly or in a combination of 2 or more of it.

In this specification, the resin composition containing an organic solvent is sometimes referred to as a resin varnish.

Illustrative examples of the organic solvent include: an alcoholic solvent such as ethanol, propanol, butanol, methyl cellosolve, butyl cellosolve, and propyleneglycol monomethyl ether; a ketonic solvent such as acetone, methyl ethyl ketone, methyl isobutyl ketone, and cyclohexanone; an ether type solvent such as tetrahydrofuran; an aromatic hydrocarbon solvent such as toluene, xylene, and mesitylene; a nitrogen atom-containing solvent such as dimethyl formaldehyde, dimethyl acetamide, and N-methyl pyrrolidone; a sulfur atom-containing solvent such as dimethyl sulfoxide; and an ester type solvent such as α-butyrolactone.

Among these, from the viewpoint of solvability, an alcoholic solvent, a ketonic solvent, a nitrogen atom-containing solvent, and an aromatic hydrocarbon solvent are preferable; an aromatic hydrocarbon solvent is more preferable, and toluene is still more preferable.

### <Production Method of the Resin Composition>

The resin composition of the present embodiment may be produced by mixing each component. At this time, these components may be dissolved or dispersed with stirring. There is no particular restriction in the conditions, such as a mixing order, a temperature, and a time; thus, the conditions may be determined as appropriate in accordance with raw materials, among other things.

In the above, the resin composition of the present embodiment has been explained; however, this disclosure also provides the following resin composition.

Namely, provided is a resin composition containing:
the thermosetting resin (A) and
a particle containing the molybdenum compound, in which
the particle containing the molybdenum compound has the molybdenum compound supported on a particle that serves as a support, and
a circularity of the particle containing the molybdenum compound is 90 or more.

There is no particular restriction in the particle that serves as the support in the particle containing the molybdenum compound. Here, illustrative examples thereof include a silica in the component (B) that supports the molybdenum compound and the inorganic filler that has been described as the component (C). The circularity of the particle that serves as the support is preferably 90 or more.

All of the preferable embodiments with regard to the type of the molybdenum compound that makes up the particle containing the molybdenum compound, the average particle diameter (D₅₀) of the particle containing the molybdenum compound, the supporting rate of the molybdenum compound in the particle containing the molybdenum compound, and the content of the particle containing the molybdenum compound in the resin composition, are the same as the preferable embodiments with regard to the component (B) in the resin composition of the present embodiment. Also, all the preferable embodiments of each component other than the particle containing the molybdenum compound are the same as the above-mentioned preferable embodiments of the resin composition of the present embodiment.

### [Prepreg]

The prepreg of the present embodiment contains the resin composition of the present embodiment and a fiber substrate.

### [Fiber Substrate]

From the viewpoints of a mechanical strength and a high-density wiring, the basis weight of the fiber substrate is preferably in the range of 50 to 150 g/m², more preferably in the range of 60 to 140 g/m², still more preferably in the range of 70 to 130 g/m², and especially preferably in the range of 80 to 120 g/m².

There is no particular restriction in the thickness of the fiber substrate. From the viewpoints of a mechanical strength and a high-density wiring, the thickness is preferably in the range of 50 to 150 μm, more preferably in the range of 60 to 140 μm, still more preferably in the range of 70 to 130 μm, and especially preferably in the range of 80 to 120 μm.

The fiber substrate has a form of a woven cloth, a unwoven cloth, a roving cloth, a chopped strand mat, a surfacing mat, and the like.

From the viewpoint of impregnation with the resin composition and so forth, the fiber substrate may be surface-treated with a coupling agent, or may be mechanically opening-treated.

Illustrative examples of the fiber for the fiber substrate include: an inorganic fiber such as a glass fiber; an organic fiber such as polyimide, polyester, and tetrafluoroethylene; and a mixture of these fibers. Among these, from the viewpoint of a low thermal expansion, an inorganic fiber is preferable, and a glass fiber is more preferable. From the same viewpoint, the fiber substrate is preferably a glass cloth.

Illustrative examples of the fiber substrate include an E glass, a D glass, a T glass, an S glass, and a quartz glass. From the viewpoint of a low thermal expansion, at least one selected from the group consisting of a D glass, a T glass, and an S glass is preferable.

Typical compositions of the E glass, the D glass, the T glass, and the S glass are as follows:
E glass: SiO₂ (52 to 56% by mass), Al₂O₃ (12 to 16% by mass), Fe₂O₃ (0 to 0.8% by mass), B₂O₃ (5 to 10% by mass), CaO (16 to 25% by mass), MgO (0 to 6% by mass), Na₂O+K₂O (0 to 2% by mass), TiO₂ (0 to 1.5% by mass), and F₂ (0 to 1% by mass);
D glass: SiO₂ (74% by mass), Al₂O₃ (0.5% by mass), B₂O₃ (22% by mass), CaO (0.5% by mass), Na₂O (1% by mass), K₂O (1.5% by mass), and Li₂O (0.5% by mass);
T glass: SiO₂ (64 to 66% by mass), Al₂O₃ (24 to 26% by mass), and MgO (9 to 11% by mass); and
S glass: SiO₂ (62 to 65% by mass), Al₂O₃ (20 to 25% by mass), CaO (0 to 0.01% by mass), MgO (10 to 15% by mass), B₂O₃ (0 to 0.01% by mass), and Na₂O+K₂O (0 to 1% by mass).

There is no particular restriction in the content of SiO₂ in the glass fiber; the content is preferably 30% by mass or more, more preferably 40% by mass or more, still more preferably 50% by mass or more, and especially preferably 60% by mass or more. There is no particular restriction in the content of SiO₂ in the glass fiber; the content is preferably 95% by mass or less, more preferably 90% by mass or less, still more preferably 80% by mass or less, and especially preferably 75% by mass or less.

There is no particular restriction in the content of SiO₂ in the glass fiber; the content is preferably in the range of 30 to 95% by mass, more preferably in the range of 40 to 90% by mass, still more preferably in the range of 50 to 80% by mass, and especially preferably in the range of 60 to 75% by mass.

When the content of SiO₂ in the glass fiber is equal to or more than the above-mentioned lower limit value, a low thermal expansion and a low warping are prone to be superior. When the content of SiO₂ in the glass fiber is equal to or less than the above-mentioned upper limit value, a drilling processability of the prepreg is prone to be further enhanced.

The prepreg of the present embodiment may be produced, for example, by the method in which the resin composition of the present embodiment is impregnated into or applied to the fiber substrate, which is then followed by heating and drying to make it to the state of B-stage.

There is no particular restriction in the temperature and time for heating and drying. From the viewpoints of productivity and appropriately bringing the resin composition of the present embodiment to the B-stage, the temperature and the time may be set in the range of 50 to 200° C. and 1 to 30 minutes, respectively.

There is no particular restriction in the content of the resin composition in the prepreg of the present embodiment. From the viewpoint of a moldability, the content is preferably in the range of 30 to 80% by mass, more preferably in the range of 35 to 70% by mass, and still more preferably in the range of 40 to 60% by mass.

### [Laminate]

The laminate of the present embodiment contains a cured product of the resin composition of the present embodiment and metal foil. The laminate having metal foil is sometimes referred to as a metal-clad laminate.

There is no particular restriction in the metal in the metal foil. Illustrative examples thereof include copper, gold, silver, nickel, platinum, molybdenum, ruthenium, aluminum, tungsten, iron, titanium, chromium, and a metal alloy containing at least one metal element described above.

The laminate of the present embodiment may be produced, for example, by the method in which the metal foil is disposed on one surface or both surfaces of the prepreg of the present embodiment, which is then followed by press-molding with heating.

Usually, by this press molding with heating, the prepreg in the state of the B-stage is cured to obtain the laminate of the present embodiment.

At the time when press-molding with heating, only one prepreg may be used, or a stack of 2 or more prepregs may be used.

Illustrative examples of the press-molding equipment with heating include a multi-stage pressing machine, a multi-stage vacuum pressing machine, a continuous molding machine, and an autoclave molding machine.

There is no particular restriction in the condition of press-molding with heating. For example, the temperature of 100 to 300° C., the time of 10 to 300 minutes, and the pressure of 1.5 to 5 MPa may be used.

### [Printed Wiring Board]

The printed wiring board of the present embodiment has a cured product of the resin composition of the present embodiment.

The printed wiring board of the present embodiment may be produced, for example, with a known method by forming a conductor circuit to the cured product of the prepreg of the present embodiment. In addition, a multilayered wiring board may be produced by conducting a multilayer adhesion processing as needed. The conductor circuit may be formed, for example, by conducting as appropriate a drilling processing, a metal plating, a metal foil etching, or the like.

### [Semiconductor Package]

The semiconductor package of the present embodiment has the printed wiring board of the present embodiment and a semiconductor element.

The semiconductor package of the present embodiment may be produced, for example, with a known method in which a semiconductor chip, a memory, and the like are mounted onto the printed wiring board of the present embodiment.

### EXAMPLES

Hereinafter, the present embodiment will be described specifically by means of Examples. However, the present embodiment is not limited to Examples described below.

In each Example, the weight-average molecular weight (Mw) was measured by the method described below.

The weight-average molecular weight was determined from the calibration curve obtained by a gel permeation chromatography (GPC) using standard polystyrenes. The calibration curve was approximated in terms of a three-dimensional formula using standard polystyrenes: TSKstandard POLYSTYRENE (Type; A-2500, A-5000, F-1. F-2. F-4, F-10, F-20, and F-40) (manufactured by Tosoh Corp., trade name). The measurement condition of GPC was as follows.
Instrument:
Pump: L-6200 Type (manufactured by Hitachi High-Tech Corp.)
Detector: L-3300 Type RI (manufactured by Hitachi High-Tech Corp.)
Column oven: L-655A-52 (manufactured by Hitachi High-Tech Corp.)
Columns: Guard column; TSK Guardcolumn HHR-L+column: TSKgel G400011HR+TSKgel G200011HR (all manufactured by Tosoh Corp., trade name)
Column size: 6.0×40 mm (guard column), 7.8×300 mm (column)
Eluent: Tetrahydrofuran
Sample concentration: 30 mg/5-mL
Injection volume: 20 μL
Flow rate: 1.00 mL/minute
Measurement temperature: 40° C.

### Production Example 1: Production of Aminomaleimide Resin

Into a 5-L volume reactor capable of being heated and cooled, equipped with a thermometer, a stirrer, and a water measurement device attached to a reflux cooling tube were charged 100 parts by mass of 2,2-bis[4-(4-maleimidephenoxy)phenyl]propane, 5.6 parts by mass of a silicone compound having a primary amino groups at both terminals (primary amino group equivalent amount of 750 g/mol), 7.9 parts by mass of 3,3′-diethyl-4,4′-diaminodiphenylmethane, and 171 parts by mass of propyleneglycol monomethyl ether; then, the reaction was carried out under reflux for 2 hours. The resulting mixture was concentrated at the reflux temperature over 3 hours to obtain an aminomaleimide resin solution with the solid concentration of 65% by mass. The weight-average molecular weight (Mw) of the resulting aminomaleimide resin was about 2,700.

### [Measurement Method of Circularity]

Using a scanning electron microscope (SEM) (product name: “JSM-6010PLUS/LA”, manufactured by JEOL Ltd.), the object was observed with the magnification of 5,000, then areas and circumferential lengths of 10 particles arbitrarily chosen were measured. Next, using the area and circumferential length of each particle, the circularity thereof was calculated by the following formula. The average value was determined as the circularity of the component (B) and of the comparative component used in each example.

$$Circularity = \{ 4 π \times ( area ) \div {( Circumferential length )}^{2} \} \times 100$$

### Examples 1 to 2 and Comparative Examples 1 to 2

### (Production of Resin Composition)

The components described in Table 1 were mixed together with methyl ethyl ketone with stirring to obtain the resin composition in a state of varnish with the solid concentration of 60% by mass. Note that the blending unit of each component in Table 1 is parts by mass; in the case of a solution, this is expressed by parts by mass in terms of the solid portion.

### (Production of Prepreg)

The resin composition in the state of varnish obtained above was impregnated into a glass cloth (basis weight of 114 g/m², T glass, glass cloth thickness of 98 μm), and then, this was dried with heating at 120° C. for 3 minutes to obtain a prepreg. The content of the resin composition in the prepreg is 50% by mass.

### (Production of Copper-clad Laminate)

Above and below a stack of 7 prepregs thereby obtained, 12-μm thick copper foil (trade name “3EC-M3-VLP-12”, Rz of M-surface: 3.0 μm, manufactured by Mitsui Mining & Smelting Co., Ltd.) were disposed such that the M-surface was in contact with the prepreg. The resulting laminate was press-molded with heating at the temperature of 240° C. and with the pressure pf 3.0 MPa for 90 minutes to obtain a copper-clad laminate.

### [Evaluation Methods]

In accordance with the following methods, each evaluation was conducted. The results are summarized in Table 1.

### (Measurement Method of Misalignment Amount of Drilled Hole Position)

On 3 stacked sheets of the copper-clad laminate, aluminum foil with the thickness of 0.15 mm and a paper phenol plate with the thickness of 1.5 mm were arranged above and below respectively. Next, using a drilling machine (trade name “ND-1V212”, manufactured by Via Mechanics, Ltd.) with a drill of 0.15 mmΦ, 10,000 holes were drilled with the rotation number of 200 krpm, the moving speed of 2 m/min, and the chip load of 10 μm/rev. Of the 3 stacked sheets of the copper-clad laminate, the position misalignment at the lower side of the third sheet (drill exist side) was measured by using a hole position accuracy measuring instrument (trade name “HT-1AM”, manufactured by Via Mechanics, Ltd.). Average+3σ (σ: standard deviation) of the misalignment amount of the hole position of 10,000 holes was calculated, and this was used as the accuracy index of the hole-drilling position.

### (Measurement Method of Copper Foil Peel Strength)

The test piece was prepared by etching the copper foil of the copper-clad laminate into the shape of a straight line having the width of 5 mm. The copper foil having been processed to the straight line was attached to a small table top testing machine (trade name “EZ-TEST”, manufactured by Shimadzu Corp.), and the copper foil peel strength was measured by peeling the copper foil to the direction of 900 with the peeling speed of 50 mm/minute at room temperature (25° C.).

### (Measurement Method of Melt Viscosity)

The powdered resin in the state of B-stage that had been prepared by unstiffening the prepreg prepared in each Example was weighed (0.6 g), which was then molded to a disk-like tablet having the diameter of 20 mm using a tableting machine. The melt viscosity of this tablet as the measurement sample was measured using a rheometer (trade name “ARES-2K STD-FCO-STD”, manufactured by Rheometrics Inc.) with the temperature raising rate of 3° C./minute, the load of 0.2 N, and the temperature range of 50 to 200° C. to obtain the minimum melt viscosity thereof.

### (Evaluation Method of Moldability)

The copper foil on both sides of the double-sided copper-clad laminate was removed by etching, and the exposed surface of the cured prepreg was visually observed. The case in which no void nor scar was observed was classified as “A”, and the case in which a void or a scar was observed was classified as “C”.

TABLE 1

| | | | Example | | Comparative Example | |
|---|---|---|---|---|---|---|
| | | | 1 | 2 | 1 | 2 |
| Blending | Component (A) | Thermosetting resin 1 | 80.0 | 80.0 | 80.0 | 80.0 |
| composition | | Thermosetting resin 2 | 20.0 | 20.0 | 20.0 | 20.0 |
| (parts by | Component (B) | Zinc molybdate-supporting silica | 5.0 | 25.0 | | |
| mass) | Comparative component | Zinc molybdate-supporting talc | | | | 25.0 |
| | Component (C) | Fused silica | 145.0 | 125.0 | 150.0 | 125.0 |
| | Component (D) | Curring accelerator | 0.5 | 0.5 | 0.5 | 0.5 |

| | | | | | |
|---|---|---|---|---|---|
| Evaluation | Misalignment amount of drilled hole position (average + 3σ) (μm) | 80 | 20 | 120 | 20 |
| results | Copper foil peel strength (kN/m) | 0.7 | 0.8 | 0.6 | 0.2 |
| | Melt viscosity (Pa · s) | 2,000 | 2,000 | 2,000 | 10,000 |
| | Moldability | A | A | A | C |

The details of each component described in Table 1 are as follows.

### [Component (A)]

Thermosetting resin 1: Aminomaleimide resin prepared in Production Example 1
Thermosetting resin 2: Biphenylaralkyl type epoxy resin, “NC-3000” manufactured by Nippon Kayaku Co., Ltd., epoxy equivalent of 275 g/eq.

### [Component (B)]

Zinc molybdate-supporting silica (silica that supports zinc molybdate): average particle diameter (D₅₀) of 0.6 μm, circularity of 99, and 1 to 30% by mass of the zinc molybdate supporting rate

### [Comparative Component]

Zinc molybdate-supporting talc (talc that supports zinc molybdate): flake-like, circularity of less than 90, and 20% by mass of the supporting rate of zinc molybdate

### [Component (C)]

Fused silica: Average particle diameter (D₅₀) of 0.5 μm, spherical fused silica

### [Component (D)]

Curing accelerator: Isocyanate-masked imidazole, manufactured by DKS Co. Ltd., trade name “G-8009L”

From Table 1, it can be seen that the resin compositions of Example 1 and Example 2 are low in the misalignment amount of the drilled hole position and high in the copper peel strength, indicating that they are superior in a drilling processability and a copper foil adhesivity. In addition, the resin compositions of Example 1 and Example 2 have a low melt viscosity and a superior moldability. On the contrary, the resin composition of Comparative Example 1 not containing the component (B) is inferior in a drilling processability and a copper foil adhesivity, and the resin composition of Comparative Example 2 is inferior in a copper foil adhesivity.

1. A resin composition comprising (A) a thermosetting resin and (B) a molybdenum compound supported on a silica.

2. The resin composition according to claim 1, wherein the component (B) is spherical.

3. The resin composition according to claim 1, wherein an average particle diameter (D50) of the component (B) is 0.1 to 20 μm.

4. The resin composition according to claim 1, wherein a supporting rate of the molybdenum compound in the component (B) is 5 to 40% by mass.

5. The resin composition according to claim 1, wherein the molybdenum compound is a metal molybdate salt.

6. The resin composition according to claim 1, wherein a content of the component (B) relative to total amount of a solid portion (100% by mass) in the resin composition is 0.1 to 20% by mass.

7. The resin composition according to claim 1, wherein the thermosetting resin (A) comprises at least one selected from the group consisting of a maleimide resin having at least one N-substituted maleimide group and a derivative of the said maleimide resin.

8. The resin composition according to claim 7, wherein the thermosetting resin (A) further comprises an epoxy resin.

9. A prepreg comprising the resin composition according to claim 1 and a fiber substrate.

10. The prepreg according to claim 9, wherein the fiber substrate is a glass cloth.

11. A laminate having a cured product of the resin composition according to claim 1 and metal foil.

12. A printed wiring board having a cured product of the resin composition according to claim 1.

13. A semiconductor package having the printed wiring board according to claim 12 and a semiconductor element.
